(19) United States
(12) Patent Application Publication
(10) Pub. No.: US 2018/0308758 A1
(43) Pub. Date: Oct. 25, 2018

(54) Methods of Forming Sources and Drains for FinFETs Using Solid Phase Epitaxy With Laser Annealing

(71) Applicant: Ultratech, Inc., San Jose, CA (US)

(72) Inventor: Michael H. Willemann, Waterford, NY (US)

(21) Appl. No.: 15/948,627

(22) Filed: Apr. 9, 2018

Related U.S. Application Data
(60) Provisional application No. 62/488,072, filed on Apr. 21, 2017.

(51) Int. Cl. H01L 21/8234; H01L 21/02; H01L 21/308; H01L 29/78

(52) U.S. Cl. CPC H01L 21/823418; H01L 21/823431; H01L 29/7851; H01L 21/02675; H01L 21/308; H01L 21/02592

(57) ABSTRACT

Methods disclosed herein include replacing top portions of source and drain sections of a finFET structure having sidewalls and a first doping with doped amorphous silicon (a-Si) or amorphous silicon germanium (a-SiGe) having a second doping opposite to a first doping and that extends above the sidewalls. Disclosed method also include performing sub-melt laser annealing of the a-Si or a-SiGe to respectively form c-Si or c-SiGe to define the source and drain regions of the finFET. Unconverted a-Si or a-SiGe is removed. The source and drain regions so formed include expanded-area portions that extend beyond the tops of the sidewalls.

### RELATED APPLICATION DATA

This application claims the benefit of priority of U.S. Provisional Patent Application Ser. No. 62/488,072, filed Apr. 21, 2017, and titled “Methods of Forming Sources and Drains for FinFETs Using Solid Phase Epitaxy With Laser Annealing”, which is incorporated by reference herein in its entirety.

### FIELD

The present disclosure relates to method of forming CMOS transistors and in particular relates to methods of forming sources and drains for finFETs using solid phase epitaxy with laser annealing.

### BACKGROUND

Modern electronics employ semiconductor integrated circuits that include transistors to switch electronic signals. Modern transistors are field-effect transistors or “FETs”, with each FET including a source region (“source”) and a drain region (“drain”) electrically connected by a conducting channel, and a gate. The gate is conducting and electrically isolated from the conducting channel by a dielectric material. A voltage applied to the gate is used to control the flow of current between the source and the drain through the conducting channel. The most common type of FET used in integrated circuits is a metal-oxide semiconductor FET, referred to in the art as a MOSFET. A P-channel MOSFET uses P-type sources and drains in a N-type body and employs holes as the carrier and is referred to as a PMOS. Likewise, an N-channel MOSFET uses N-type sources and drains formed in a P-type body and employs electrons as the carrier and is referred to as a NMOS. The design of integrated circuits using NMOS and PMOS is generally referred to as CMOS (“complementary” MOS).

One of the main benefits of MOSFETs is that they can be made on very small scales to provide for increasing levels of integration, improving functionality at reduced cost. Unfortunately, increasing integration and performance demands require size reductions in the main components of a MOSFET that can adversely impact their performance.

Efforts to overcome performance issues due to increasing integration include fabricating the transistor channel as a vertical “fin” configuration, with the MOSFET being referred to in this case as a “finFET.” The fin configuration of a finFET allows for greater scaling of the CMOS dimensions while improving drive current and electrostatic control. FinFETs are described in U.S. Pat. No. 6,413,802, U.S. Pat. No. 6,642,090, and U.S. Pat. No. 6,645,797, which are incorporated by reference herein.

The source and drain regions of a standard finFET are formed by a selective chemical vapor deposition process that grows doped crystalline silicon or silicon alloyed with germanium at various concentrations (SiGe). A problem with this approach is that the process is slow, so that it takes a relatively long time to form the source and drain regions. Deposition rates at typical process temperatures disclosed in the literature vary from approximately 0.1 to 1 nm per minute. The slowness of the process has an adverse impact on CMOS wafer throughput, which translates into a higher cost per CMOS wafer.

### SUMMARY

An aspect of the disclosure is a method of forming source and drain regions for a finFET. The method includes:
a) defining a c-Si fin having a first doping, opposite sides, a top section having a top portion with a top, and also having a source section, a drain section and a central section that separates the source and drain sections;
b) covering the top and opposite sides of the central portion of the c-Si fin with a gate material to define the gate of the finFET;
c) covering the sides of the source and drain sections with sidewalls made of a dielectric material, wherein the sidewalls have tops;
d) replacing the top portions of the source and drain sections with doped amorphous silicon (a-Si) or amorphous silicon germanium (a-SiGe) having a second doping opposite to the first doping, wherein the doped a-Si or a-SiGe extends beyond the tops of the sidewalls; and
e) performing sub-melt laser annealing of the a-Si or a-SiGe having the second doping to respectively form c-Si or c-SiGe to define the source and drain regions of the finFET, wherein the source and drain regions include respective expanded-area portions that extend beyond the tops of the sidewalls; and
f) removing any a-Si or a-SiGe that was not converted to c-Si or c-SiGe during act e).

Another aspect of the disclosure is the method described above, wherein the acts c) and d) comprise: depositing a dielectric material over the tops and the sides of the source and drain sections to define tops of the dielectric material that reside directly above the source and drain sections; selectively masking the dielectric material to leave the tops of the dielectric material exposed; and etching through the tops of the dielectric material and into the source and drain sections to remove the top portions of the source and drain sections to define respective source and drain well structures having shortened source and drain top sections.

Another aspect of the disclosure is the method described above, wherein act d) comprises: blanket depositing as a layer the doped a-Si or the doped a-SiGe so that a portion of the layer fills the source and drain well structures and resides upon the shortened source and drain top sections.

Another aspect of the disclosure is the method described above, wherein act a) comprises defining multiple c-Si fins and further comprising simultaneously performing acts b) through f) on the multiple c-Si fins to form multiple source and drain regions for multiple finFETs.

Another aspect of the disclosure is the method described above, wherein the act e) of sub-melt laser annealing includes scanning a laser beam over the doped a-Si to have a dwell time in the range from 10 ns to 500 ns.

Another aspect of the disclosure is the method described above, wherein the scanning laser beam has a wavelength in the range from 200 nm to microns.

Another aspect of the disclosure is a finFET product formed by the above-described methods.

Another aspect of the disclosure is a method of forming source and drain regions for finFETs, comprising:
a) defining multiple c-Si fins each having a first doping, opposite sides, a top section having a top portion with a top, and also having a source section;
b) covering the top and opposite sides of the central portion of each of the c-Si fins with a gate material to define the gates of the finFETs;
c) covering the sides of the source and drain sections of each c-Si fin with sidewalls made of a dielectric material;
d) replacing the top portions of the source and drain sections of each of the c-Si fins with a doped amorphous material comprising either doped amorphous silicon (a-Si) or doped amorphous silicon-germanium (a-SiGe) having a second doping opposite to the first doping, wherein the doped amorphous material extends beyond the tops of the sidewalls;
e) performing sub-melt laser annealing of the a-Si to form doped c-Si having the second doping to define the source and drain regions of the finFETs, wherein the source and drain regions include respective expanded-area portions that extend beyond the tops of the sidewalls; and
f) removing any of the doped amorphous material that was not converted to doped crystalline material in act e).

Another aspect of the disclosure is a method of forming a source region and a drain region for a finFET, comprising:
a) defining a c-Si fin having a first doping, opposite sides, a top section having a top portion with a top, and also having a source section and a drain section;
b) covering the top and opposite sides of the central portion of the c-Si fins with a gate material to define the gates of the finFETs;
c) covering the sides of the source and drain sections with sidewalls made of a dielectric material;
d) selectively removing the top portions of the source and drain sections;
e) replacing the top portions with a doped amorphous material that comprises either Si or SiGe, the doped amorphous material having a second doping opposite to the first doping using a blanket deposition of the doped amorphous material so that the doped amorphous material extends beyond the tops of the sidewalls;
f) performing sub-melt laser annealing to convert the doped amorphous material to a doped crystalline material comprising either Si or Ge and having the second doping to define the source and drain regions of the finFETs, wherein the doped crystalline material beyond the tops of the sidewalls;
g) removing any of the doped amorphous material that was not converted to the doped crystalline material during act f).

Additional features and advantages are set forth in the Detailed Description that follows, and in part will be apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description explain the principles and operation of the various embodiments. As such, the disclosure will become more fully understood from the following Detailed Description, taken in conjunction with the accompanying Figures, in which:

FIG. 1A is a top-down view of an example CMOS wafer that includes a plurality of CMOS cells, with the close-up inset showing an array of finFET structures;

FIG. 1B is an elevated view that shows the portion of the array of finFET structures within the box 1B in the close-up inset of FIG. 1A;

FIG. 1C is a view looking in the x-direction (as indicated by the arrow 1C) of the finFET structures shown in the close-up inset of FIG. 1A;

FIG. 1D is a y-z cross-sectional view taken along line 1D-1D in the close-up inset of FIG. 1A taken across the gate;

FIG. 1E is an x-z cross-sectional view taken along the line 1E-1E in the close-up inset of FIG. 1A taken across the c-Si fins;

FIG. 2 is a cross-sectional view similar to FIG. 1E and shows a first step in the method of depositing a low-k dielectric layer over the c-Si fins of the finFET structure;

FIGS. 3A and 3B show a second step in the method of etching the dielectric layer to selectively remove portions of the dielectric layer as well as portions of the c-Si fins that reside between the dielectric layer sidewalls;

FIG. 4 shows a third step in the method of blanket depositing a layer of doped amorphous material atop the finFET structure of FIG. 3B;

FIGS. 5A and 5B are schematic diagrams that illustrate how a N-doped amorphous silicon layer and a P-doped amorphous SiGe layer can be formed on respective NFET and PFET sides of the cell;

FIG. 5C is a schematic cross-sectional diagram that shows the result of the two-step deposition process for forming the doped amorphous material layer, with the N-doped Si layer and P-doped SiGe layer formed on the respective NFET and PFET sides of the cell;

FIG. 6A shows a fourth step in the method of performing sub-melt laser annealing of the finFET structure of FIG. 4 using a laser beam to perform solid phase epitaxy;

FIG. 6B shows the results of the laser annealing step of FIG. 6A and showing the resulting crystalline silicon fins that have mushroom-like top portions;

FIG. 7A is similar to FIG. 6B and shows a fifth step in the method wherein the portion of the doped amorphous material that was not crystallized during the laser annealing step is removed to expose the crystalline silicon fins, which now serve as the sources and drains for the finFET;

FIG. 7B shows x-z and y-z close-up cross-sectional views of the c-Si fin of FIG. 7A; and

FIG. 8 is similar to FIG. 1C and shows an example of a final finFET that includes the newly formed c-Si fins of FIGS. 6B, 7A, and 7B.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

Cartesian coordinates are shown in some of the Figures for ease of illustration and explanation and are not intended to be limiting as to orientation and direction.

The discussion below refers to doped Si. Examples of N-type and P-type dopants for Si are well known in the art (e.g., boron is a known P-type dopant while phosphorus is a known N-type dopant). In the discussion below, N-type and P-type (or just N and P) dopings are “opposite” dopings. Thus, reference to a first doping being opposite to a second doping means that one of the dopings is N doping while the other is P doping.

CMOS Wafer and finFET Structures

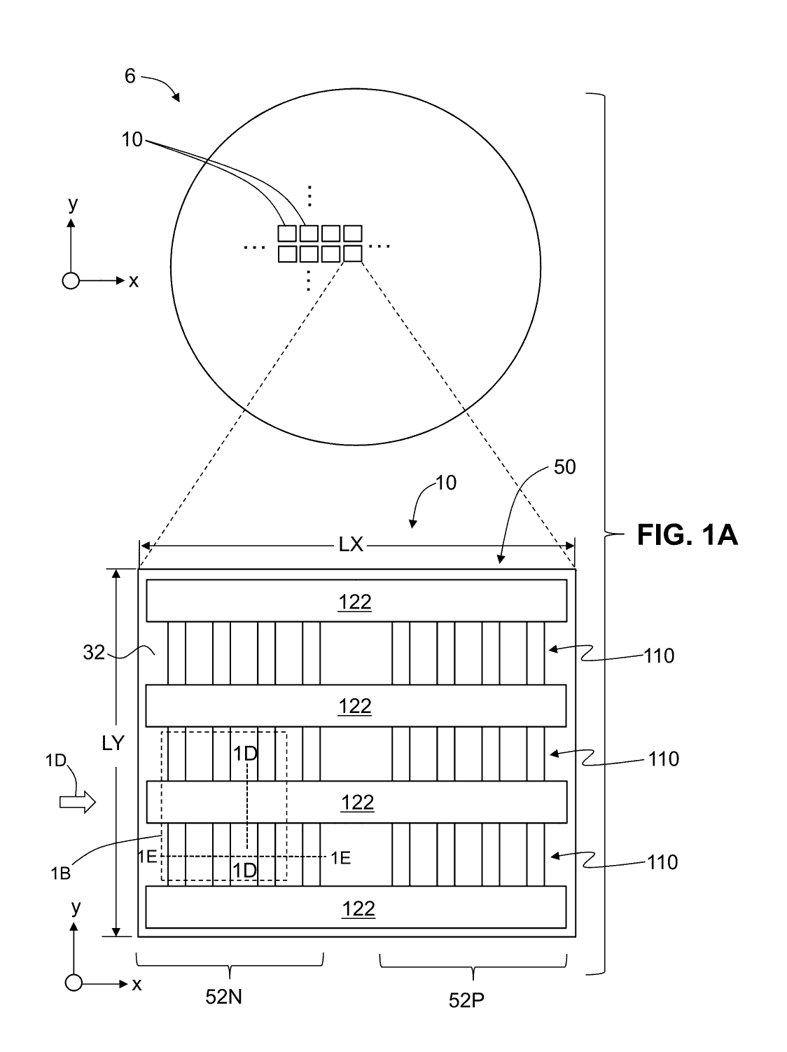

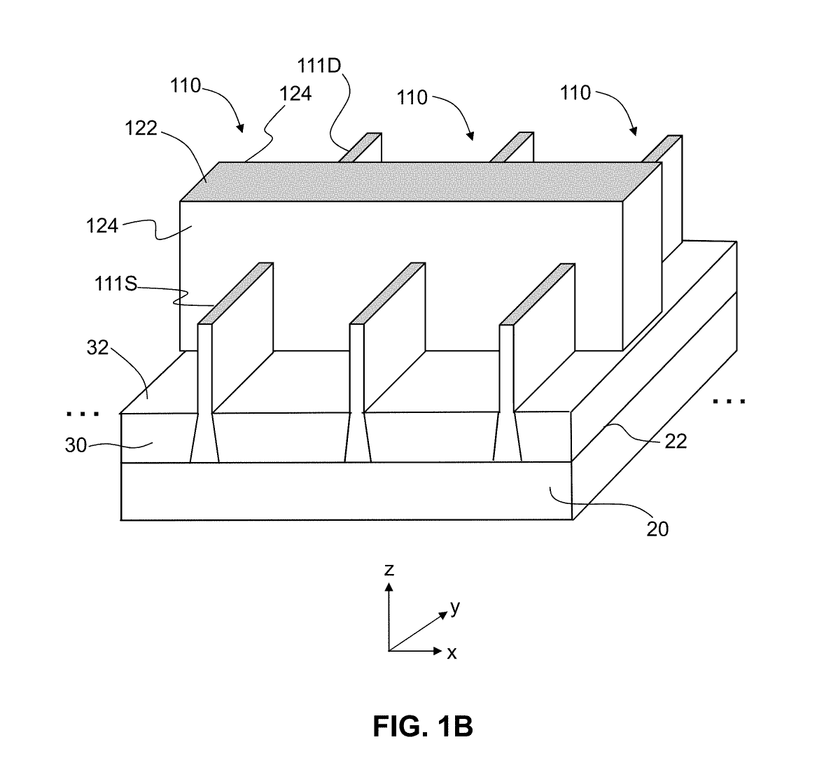

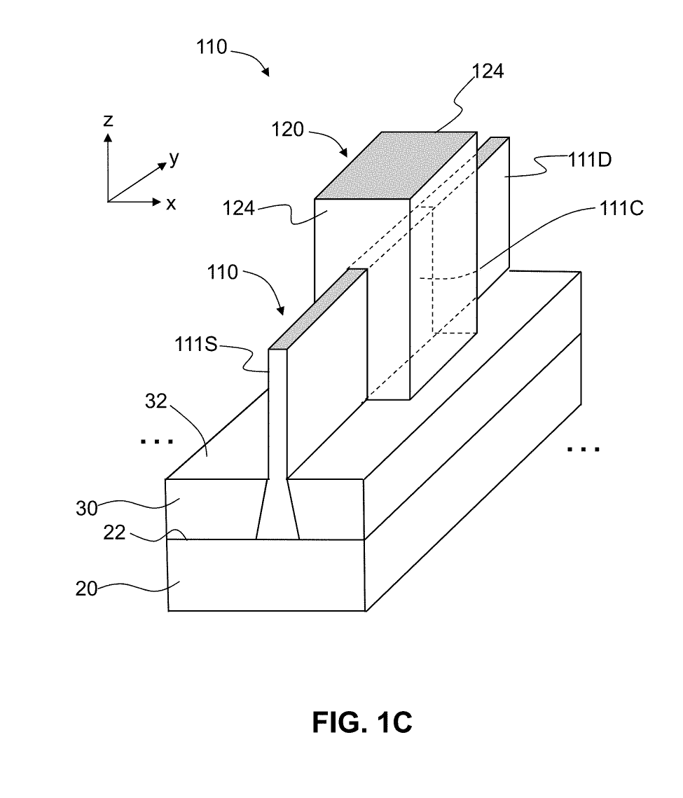

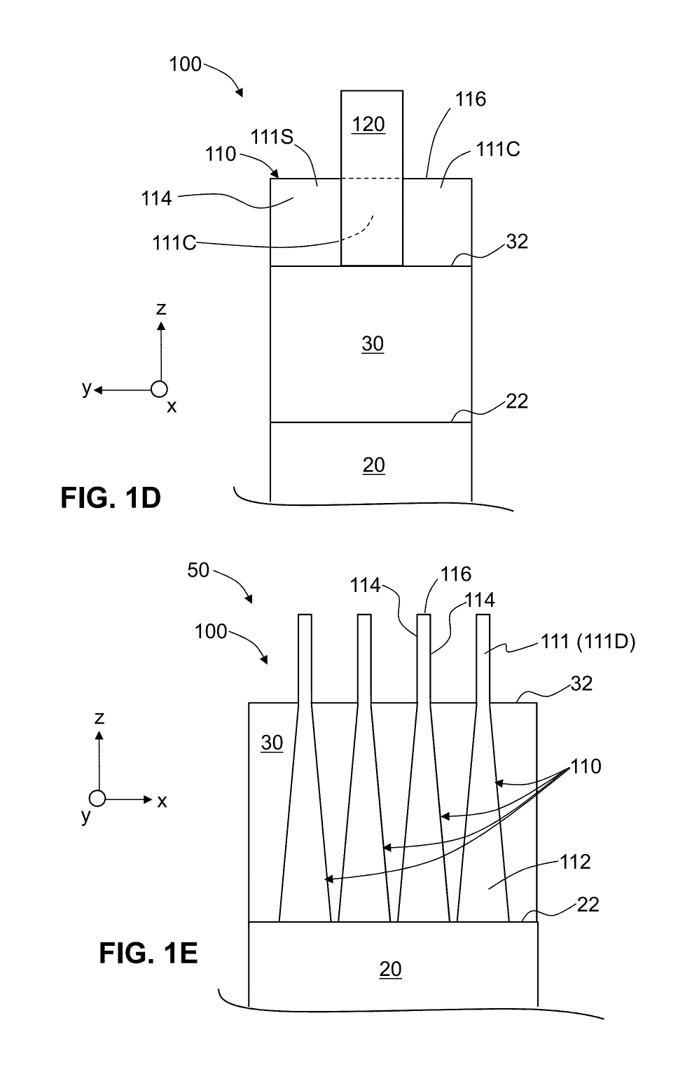

FIG. 1A is a top-down view of an example CMOS wafer 6 that includes a plurality of CMOS cells (“cells”) 10. In an example, the CMOS wafer 6 comprises a crystalline silicon (c-Si) base 20 having a top surface 22 upon which is formed an oxide layer 30 having a top surface 32. An example oxide for the oxide layer 30 is silicon dioxide (see FIGS. 1B through 1C, introduced and discussed below). In an example, the CMOS wafer 6 can have can have a silicon-on-oxide (SOI) configuration.

FIG. 1A includes a close-up top-down view of an example cell 10, shown as a standard 9T4 cell used in CMOS device fabrication. The cell 10 comprises an assembly or array 50 of finFET structures 100. The cell 10 can be divided into an N-side 52N and a P-side 52P associated with the formation of N-finFETs (“NFETS”) and P-finFETs (PFETs), as described below. Example dimensions of cell 10 are scaled based on the scaling rules used for that node. For example, a first commercial generation of finFET would have a cell size of approximately 600 nm×360 nm. In the subsequent generation, the cell size would be approximately 420 nm×280 nm, and so forth.

FIG. 1B is an elevated view that shows the portion of the array of finFET structures within the box 1B in the close-up inset of FIG. 1A. FIG. 1C is similar to FIG. 1B and shows a single finFET structure 100. FIG. 1D is a side view looking in the y-direction of the finFET structures 100 shown in the close-up inset of FIG. 1A (see the arrow 1D) and in the elevated view of FIG. 1B. FIG. 1E is an x-z cross-sectional view taken along the line E-E in the close-up inset of FIG. 1A.

The finFET structures 110 in the array 50 are shown in an initial form on the way to defining fully functional finFETs as part of a CMOS device. This requires additional processing of the finFET structures 100 using the methods described below.

With particular reference to FIGS. 1C and 1D, each finFET structure 100 includes a crystalline silicon (c-Si) fin 110 that are used to form the source regions 211S and the drain regions 211D of the final finFETs, as discussed below. The c-Si fins 110 extend upward from the top surface 22 of the base 20 and pass through the oxide layer 30 and extend beyond the top surface 32 of the oxide layer. Each c-Si fin 110 has a top section 111 that resides above the oxide layer 130 and a bottom section 112 that resides within the oxide layer. The top section has sides 114 and a top 116 and also has a source section 111S, a drain section 111D and a center or channel section 111C (see FIG. 1C) that later will respectively define the source 211S, the drain 211D and the channel 211C of the final finFET.

Note that in an example, the oxide layer 30 supported by the base 20 defines a shallow trench isolation (STI) feature for the bottom sections 112 of the c-Si fins 110, as best seen in FIG. 1D. At this point in the process, the c-Si fins 110 are uniformly doped, i.e., are either N-doped or P-doped, depending on whether N-finFETS or P-finFETs are being formed. In the example shown in the close-up view of FIG. 1A, the c-Si fins 110 on the N-side 52N are P-doped in anticipation of forming N-finFETs, while the c-Si fins on the P-side 52P are N-doped in anticipation of forming P-finFETs.

Each finFET structure 100 also includes a gate 120. The gates 120 are defined by gate lines 122 of a gate material (e.g., metal or polysilicon), wherein the gate lines run perpendicular to the c-Si fins 110. In an example, the c-Si fins 110 are formed from a c-Si substrate via an etch process and the gate lines 120 are formed over the c-Si fins so that each gate 120 reside over the top 116 and opposite sidewalls 114 of the corresponding channel sections 111C of a given c-Si fin 110. Here, the term “gate” is used to define the portion of a given gate line 222 that surrounds “three sides” (or more accurately, the top and two sides) of the channel section 111C of a given c-Si fin 110, as best seen in FIG. 1C. The ellipsis ( . . . ) in FIG. 1C indicate that the array 50 runs in the +x and the −x direction and that only one section of the array with one finFET structure 100 is being shown. The gate 120 so formed is said to be self-aligned, with the gate serving as a mask for forming the source section 111S and the drain section 111D, which reside on opposite sides 124 of the gate (see FIG. 1C).

Up to this point, the CMOS wafer 6 and cells 10 are formed using standard semiconductor manufacturing techniques and methods and the finFET structures 100, which represent the building blocks for forming the final finFETs using the methods disclosed herein.

Methods

An aspect of the methods disclosed begins with the CMOS wafer 6 and the arrays 50 of finFET structures 100 of FIGS. 1A through 1E and involves five main process or method steps (the terms “process” and “method” are used interchangeably herein).

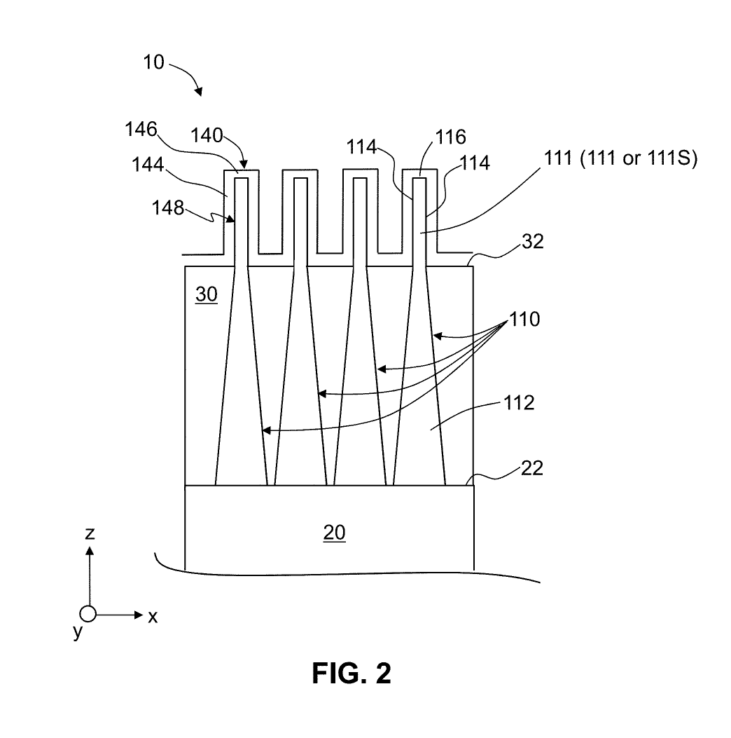

The first main step of the method involves adding a substantially conformal low-k dielectric layer 140 to the finFET structures 100. FIG. 2 is a cross-sectional view similar to FIG. 1E and shows the deposited dielectric layer 40 covering the c-Si fins 110. In FIG. 2 and going forward, the top section 111 of the c-Si fins 110 can be either the source section 111S or the drain section 111D. In an example, the dielectric layer 140 can be SiOₓ, SiNₓ, or SiOₓN_{y}, with possible additions of boron or carbon. The dielectric layer 140 defines sidewalls 144 on the sides 114 of the top sections 111 of the c-Si fins 110. The sidewalls 144 later serve to electrically isolate adjacent finFETs and gates. The dielectric layer 140 also defines tops 146 that reside directly upon the tops 116 of the c-Si fins 110. The sidewalls 144 and the tops 146 together define an interior 148 in which the corresponding top sections 111 of the c-Si fins 110 are now enclosed.

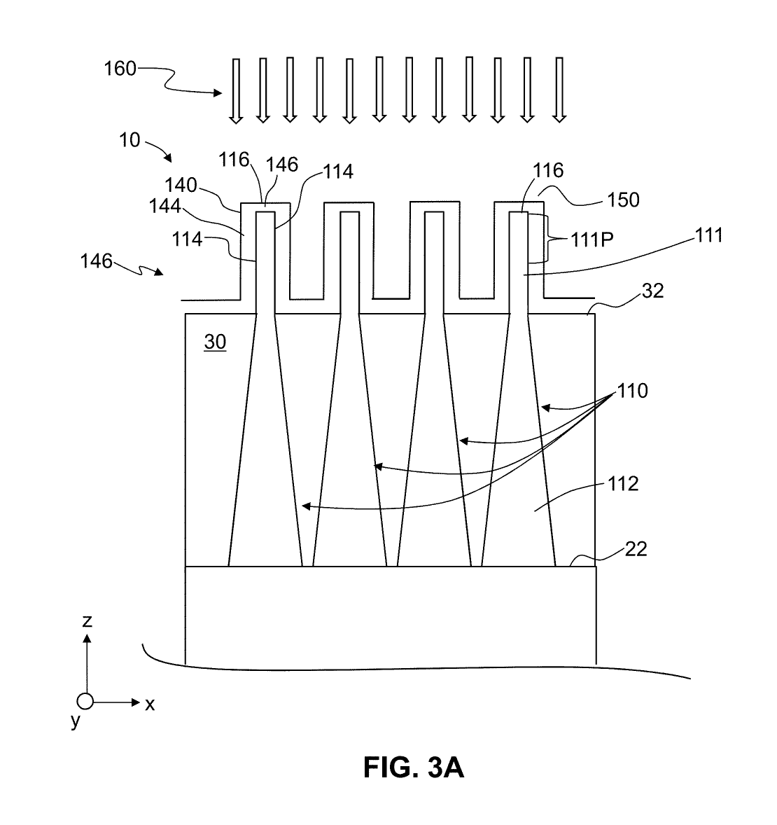

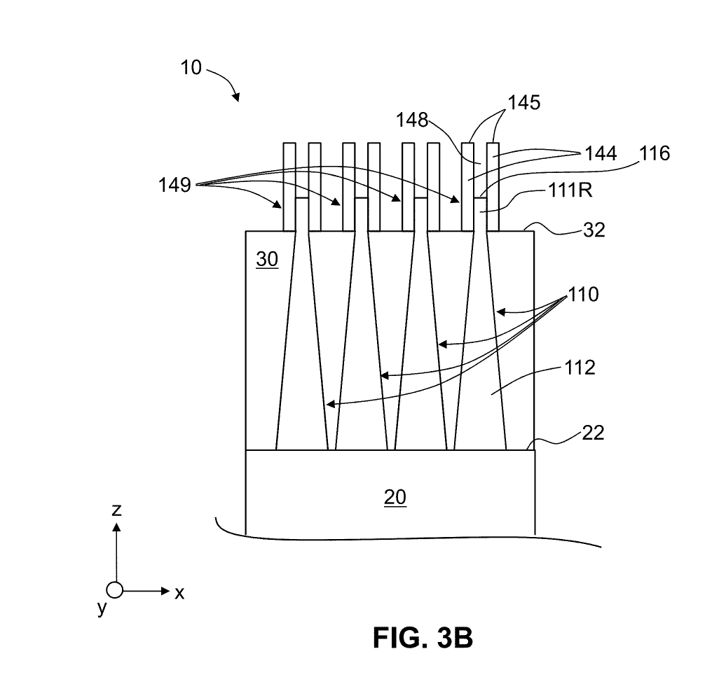

The second step of the method is illustrated in FIG. 3A and involves performing selective masking of the dielectric layer 140 using standard lithography techniques. FIG. 3A shows an example etch process 160 (e.g., a reactive-ion etching process) used to selectively remove the portions of the dielectric layer 140 that reside on the tops 116 of the c-Si fins 110. The etch process 160 also selectively removes a top portion 111P of each of the top sections 111 of the c-Si fins 110 (see FIG. 3A) so that pairs of dielectric sidewalls 144 have tops 145 and now contain a shortened or “reduced” top sections 111R, as shown in FIG. 3B. Each pair of dielectric sidewalls 144 and the shortened top section 111R therein defines a well structure 149. The shortened top sections 111R can be for the source section 111S or the drain section 111D of the c-Si fin 110. Thus, for each finFET structure 110, there is one well structure 149 for the source section 111S and another well structure for the drain section 111D.

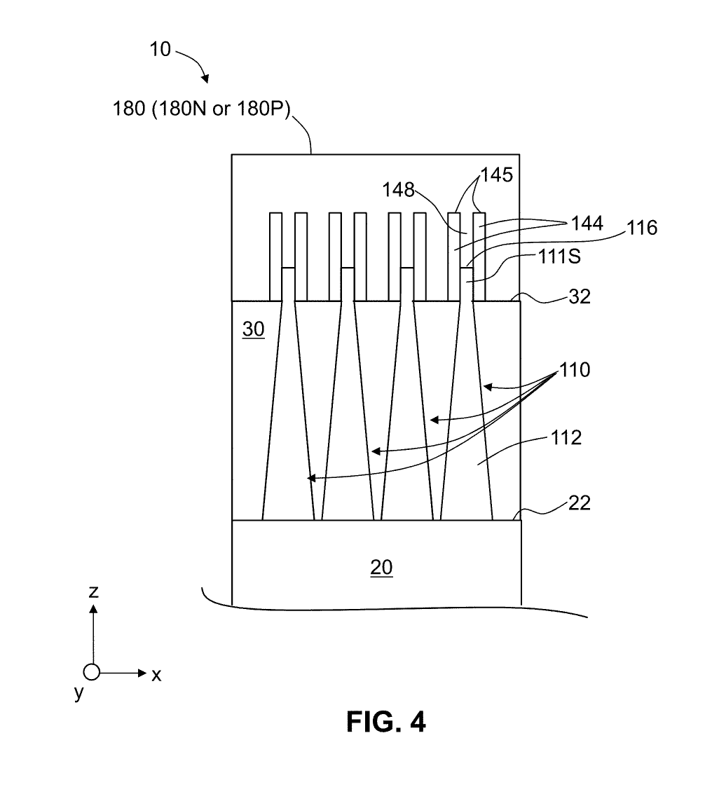

The third step of the method involves performing a blanket deposition of a doped amorphous material 180 that comprises either amorphous silicon (a-Si) or amorphous silicon-germanium (a-SiGe). The doped amorphous material 180 can be deposited as a layer over the finFETs 110, as shown in FIG. 4, and so is also referred the doped amorphous material layer 180. The composition of the doped amorphous material 180 depends on the dopant of the c-Si fins 110. If the c-Si fins 110 are N-doped, then the doped amorphous material comprises or consists of P-doped a-SiGe 180P. If the c-Si fins are P-doped, then the doped amorphous material 180 comprises or consists of N-doped a-Si.

Reference to a doped amorphous material 180 means that the doping can be N or P, with the specific type of doping indicated as 180N and 180P as necessary for clarity. Note how the doped amorphous material layer 180 fills the interiors 148 of the well sections 149 and resides atop the shortened top section 111R of the c-Si fins 110 therein. Note also in the example shown that the doped amorphous material 180 a-Si overfills the well sections 149 so that some of the material resides above the tops 145 of the sidewalls 144.

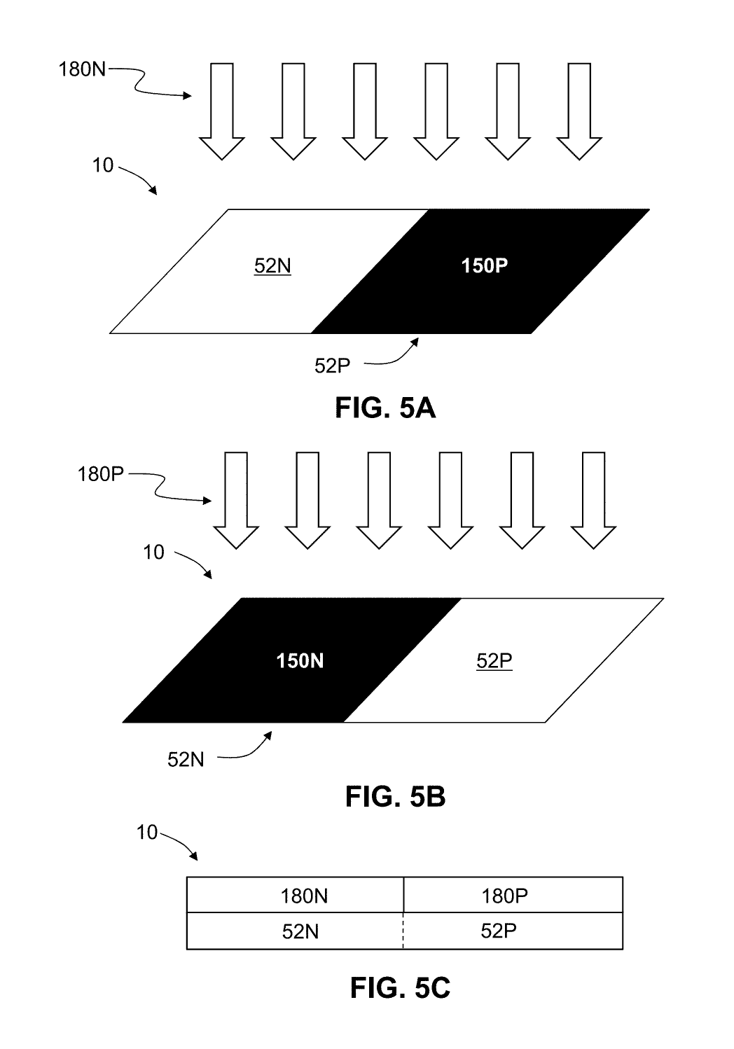

In an example, the third step can include depositing a N-doped amorphous silicon (a-Si) layer 180N over the N-side 52N of the cell 10 and a P-doped a-SiGe layer 180P over the P-side 52P of the cell. The deposition of the doped a-SI layers 180N and 180P can be accomplished by standard lithography process that selectively masks one of the N-side 52N and the P-side 52P while the other is side is being coated with the appropriately doped a-Si layer 180. Thus, with reference to FIG. 5A, the N-side 52N of the cell 10 is uncovered while the P-side 52P is masked off with mask feature 150P. The N-doped a-Si layer 180N is then deposited over the entire cell 10. The masking layer 150P and the N-doped a-Si layer 180N thereon is then removed from P-side 52P of the cell 10. With reference now to FIG. 5B, the P-side 52P of the cell 10 is uncovered while the N-side 52N is masked off with a mask feature 150N. The P-doped a-Si layer 180P is then deposited over the entire cell 10. The masking layer 180N and the P-doped a-Si layer 180P thereon is then removed from N-side 52N of the cell 10. The result, as shown in the schematic cross-sectional view of FIG. 5C, is that the N-side 52N and the P-side 52P of the cell 10 are respectively coated with an N-doped a-Si layer 180N and a P-doped a-Si layer 180P.

In an example, the deposition of the doped amorphous material layer 180 can be performed using plasma-enhanced (PE) CVD at low pressure with a hydrogen ambient. A low deposition temperature (e.g., in the range from approximately 25° C. to approximately 300° C.) can be used to minimize surface mobility of adsorbed reactants and spontaneous formation of crystal nuclei. In an example, the step of depositing the doped amorphous material layer 180 involves only one type of dopant, i.e., either N or P dopant.

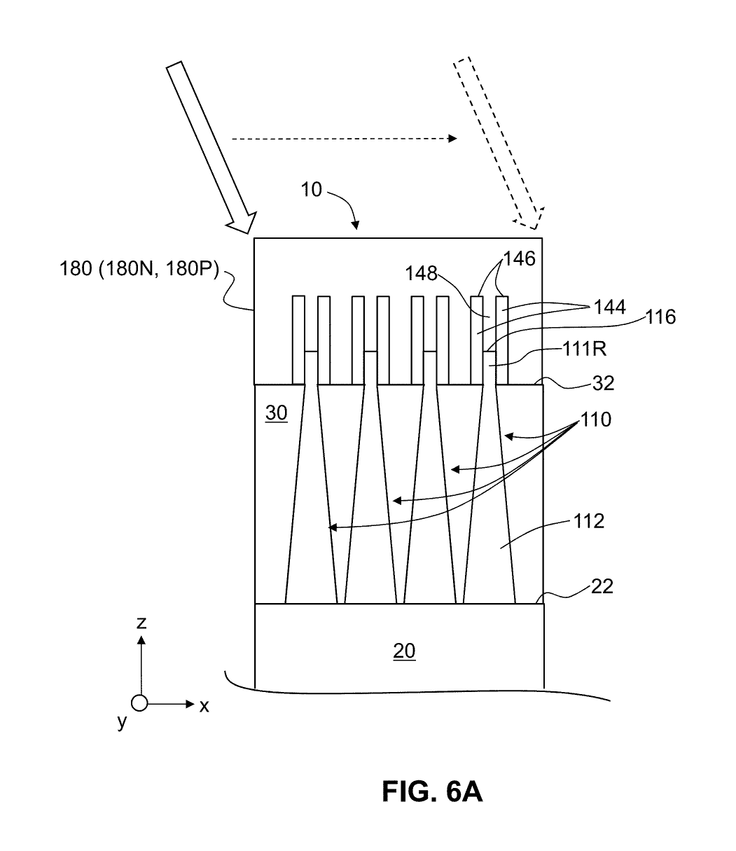

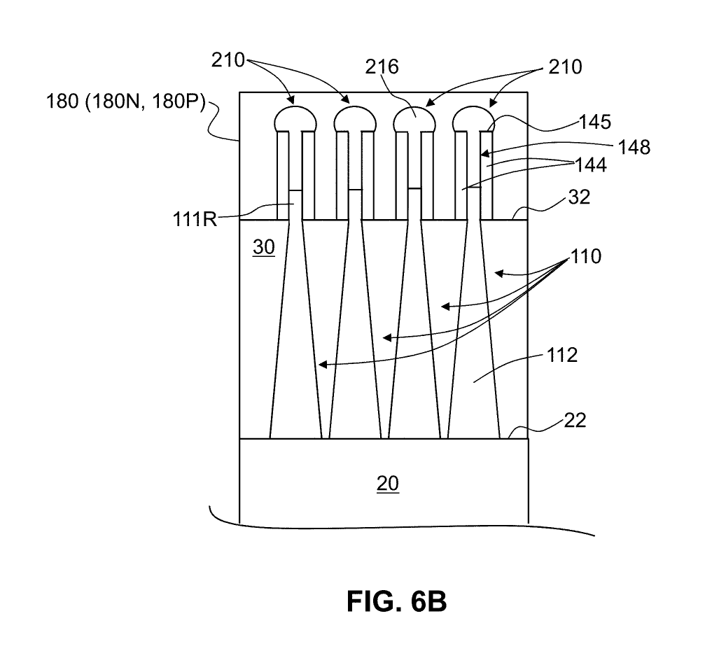

FIG. 6A shows the fourth step of the method, which involves performing laser annealing of the doped amorphous material layer 180 using an annealing laser beam LB to perform solid phase epitaxy (SPE). The laser annealing is sub-melt and serves to recrystallize the portions of the doped amorphous material layer that now reside atop the shortened top section 111R and within the well structures 149, which were formed previously from the dielectric layer 140. The recrystallization also extends into the portion of the doped amorphous material layer 180 that reside adjacent the tops 146 of the sidewalls 144. The recrystallization process is enabled by the shortened top sections 111R of the c-Si fins 110 on which the doped a-Si layer 150 reside by serving as a template for crystalline growth. Thus, the laser annealing step is used to convert at least a portion of the doped amorphous material layer 180 to a doped crystalline material layer.

In an example, the laser annealing is carried out with dwell times in the range from 10 ns to 500 ns. The sub-melt regime is used to suppress homogenous nucleation of poly Si or heterogeneous nucleation from impurities, such as surface particles, plasma damage, etc. Example sub-melt (or non-melt) laser annealing are described in U.S. Pat. No. 9,490,128 and U.S. Pat. No. 6,747,245, which are incorporated by reference herein. In an example, the laser beam LB can have wavelength in the ultraviolet (UV), the visible or the near-infrared range, e.g., in the range from 200 nm to 11 microns.

FIG. 6B shows the result of the annealing and re-crystallization process, which transforms the old c-Si fins 110 into new c-Si fins 210 having the opposite doping as the old c-Si fins.

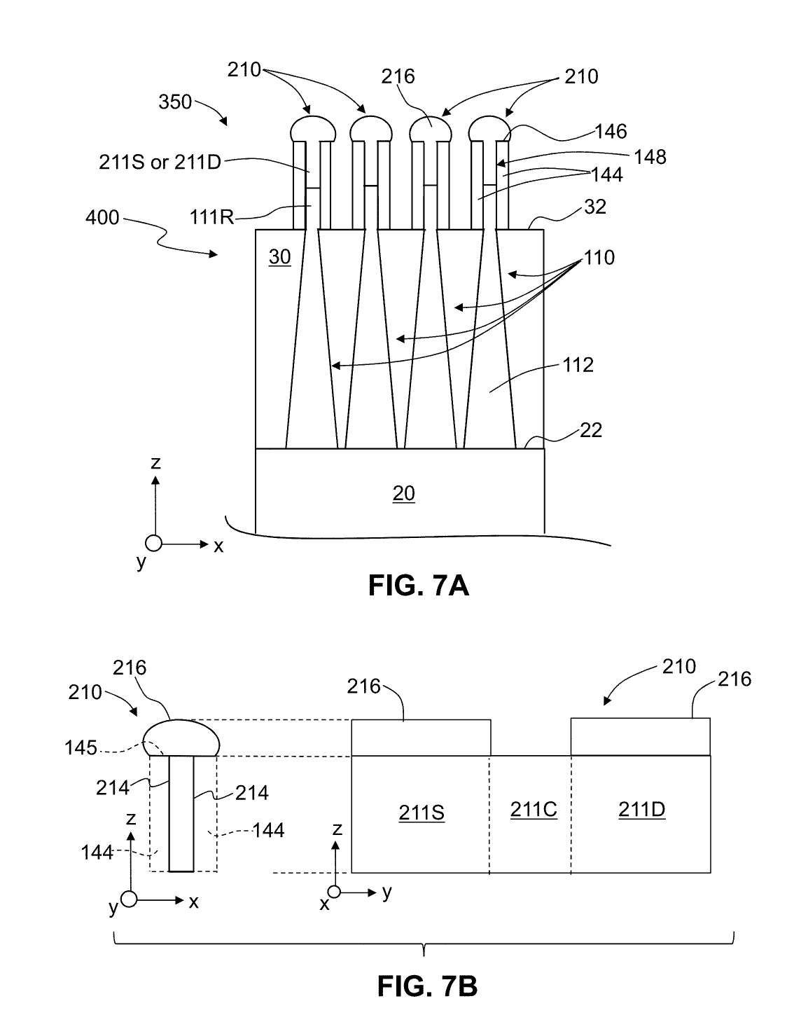

The fifth step of the method involves removing the remaining portions of the doped amorphous material layer 180 that was not converted to the doped crystalline material during the laser annealing step. This can be accomplished for example by using dilute aqueous HF, NH₄OH, or HCL. Selective dry or gaseous etches can also be used. FIG. 7A is a cross-sectional view of the new c-Si fins 210 as part of an array 350 of finFETs 400. FIG. 7B shows x-z and y-z close-up cross-sectional views of the c-Si fin 210.

The new c-Si fins 210 each has a source section (source) 211S, a drain section (drain) 211D and a central or channel section 211C. The c-Si fin 210 has opposite sides 214. The source and drain sections 211S and 211D of the c-Si fin 210 have a first doping (N or P) and each have an expanded-area portion 216 that extends above the tops 145 of the sidewalls 144, while the channel section 211C has a second doping (N or P) opposite to the first doping. This is because the channel section 111C of the original c-Si fin 110 remained covered on the top 116 and two sides 114 by the gate 120 during processing (see FIG. 1C) and so its doping properties remained unchanged. In an example, the new c-Si fins 210 each has a cross-sectional shape that looks like a mushroom, with the expanded-area portion 216 defining the mushroom cap.

The original source and drain sections 111S and 111D have now been processed via laser-based SPE to form the oppositely doped source and drain sections 211S and 211D (as compared to the original source and drain sections 111S and 111D). Thus, for an original c-Si fin 110 that was N-doped, the source and drain sections 211S and 211D of the new c-Si fins 210 are now P-doped. Likewise, for an original c-Si fin 110 that was P-doped, the source and drain sections 211S and 211D of the new c-Si fins 210 are now N-doped. The source and drain sections 211S and 211D of the new c-Si fins 210 define the source and drain of the finFET while the channel section 211C defines the channel of the finFET through which the charge carriers (electrons or holes) pass between the source and the drain under the control of the gate 120. As noted above, the dielectric walls 144 on the sides electrically isolate the sources, drains, and gates from one another.

In an example embodiment, the fourth and fifth steps of the method described above can be performed on one of the N and P sides 52N and 52P of the cell 10 one at a time. Thus, the N-side 52N can be blanket deposited with N-doped a-Si 180N and then laser annealed to form the c-Si fins 210 for the N-side and then the remaining N-doped a-Si removed. This process can then be repeated for the P-side 52P to form the c-Si fins 210 for the P-side of the cell 10.

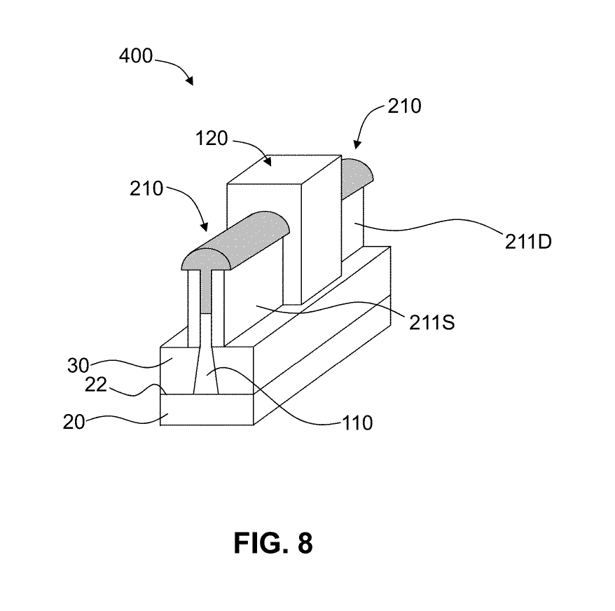

FIG. 8 is similar to FIG. 1C and shows an example of the final finFET 400 that includes the newly formed c-Si fins 210.

Once the formation of the source 211S and drain 211D are complete, standard integration and processes known to those skilled in the art are performed to form functional transistors and connect those transistors in a structured way to create logic elements. First, the spaces between the completed source and drains 211S and 211D are backfilled with a dielectric for protection from subsequent processing. The surface is then planarized using chemical mechanical polish (CMP) to expose the dummy polysilicon gates 122. The dummy gate is removed and replaced with the high-k oxide gate dielectric and the gate metals to establish the work function and threshold voltage for the NFET and PFET, respectively. Next, vias are etched in the dielectric to uncover the previously formed sources and drains. Silicide is deposited and annealed to form an electrical connection with a low Schottky barrier, and metals are deposited to fill the vias. Finally, several metal layers of increasing pitch are pattern on top in a structured way to form functional logic elements and provide voltage bias between the source and the drain and the gate and the body.

The above-described methods of forming the source and drains 211S and 211D for finFETs 100 is much faster than the prior art method of using a CVD process. Recall, the CVD crystalline growth process for forming the doped source and drain regions is done in a single step. In the methods disclosed herein, the formation of doped crystalline sources and drains is broken out into two main steps—namely, the deposition doped a-Si and then performing SPE using laser annealing to convert the doped a-Si to c-Si. It turns out that the two-step SPE process disclosed herein is significantly faster than the one-step CVD process; it is at least twice as fast and can be up to ten times faster. This faster process in turn leads to a substantial increase in the throughput (wafers per hour) of CMOS wafers, such as CMUS wafer 6, that employ finFETs.

The methods disclosed herein also result in source and drain structures that facilitate the CMOS fabrication process. For example, the expanded area of the top portions 212 of the source and drains 211S and 211D make it easier to form metal contacts when performing a subsequent metallization process for electrically interconnecting the components of the finFETs 100.

Another advantage is that the a-Si or the a-SiGe material can have a higher dopant concentration or a greater number of strain modifiers than what can be provided by the CVD process. The higher dopant concentration results in a lower contact resistance and thus a higher “on” current for the finFETs 100. In an example, the performance improvement in the “on” current can be up to about 10%.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed:

1. A method of forming source and drain regions for a finFET, the method comprising:
a) defining a c-Si fin having a first doping, opposite sides, a top section having a top portion with a top, and also having a source section, a drain section and a central section that separates the source and drain sections;
b) covering the top and opposite sides of the central portion of the c-Si fin with a gate material to define the gate of the finFET;
c) covering the sides of the source and drain sections with sidewalls made of a dielectric material, wherein the sidewalls have tops;
d) replacing the top portions of the source and drain sections with doped amorphous silicon (a-Si) or amorphous silicon germanium (a-SiGe) having a second doping opposite to the first doping, wherein the doped a-Si or a-SiGe extends beyond the tops of the sidewalls;
e) performing sub-melt laser annealing of the a-Si or a-SiGe having the second doping to respectively form c-Si or c-SiGe to define the source and drain regions of the finFET, wherein the source and drain regions include respective expanded-area portions that extend beyond the tops of the sidewalls; and
f) removing any a-Si or a-SiGe that was not converted to c-Si or c-SiGe during act e).

2. The method according to claim 1, wherein the acts c) and d) comprise:
depositing a dielectric material over the tops and the sides of the source and drain sections to define tops of the dielectric material that reside directly above the source and drain sections;
selectively masking the dielectric material to leave the tops of the dielectric material exposed; and
etching through the tops of the dielectric material and into the source and drain sections to remove the top portions of the source and drain sections to define respective source and drain well structures having shortened source and drain top sections.

3. The method according to claim 2, wherein act d) comprises:
blanket depositing as a layer the doped a-Si or the doped a-SiGe so that a portion of the layer fills the source and drain well structures and resides upon the shortened source and drain top sections.

4. The method according to claim 1, wherein act a) comprises defining multiple c-Si fins and further comprising simultaneously performing acts b) through f) on the multiple c-Si fins to form multiple source and drain regions for multiple finFETs.

5. The method according to claim 1, wherein the act e) of sub-melt laser annealing includes scanning a laser beam over the doped a-Si to have a dwell time in the range from 10 ns to 500 ns.

6. The method according to claim 5, wherein the scanning laser beam has a wavelength in the range from 200 nm to microns.

7. A finFET product formed by the process comprising:
a) defining a c-Si fin having a first doping, opposite sides, a top section having a top portion with a top, and also having a source section, a drain section and a central section that separates the source and drain sections;
b) covering the top and opposite sides of the central portion of the c-Si fin with a gate material to define the gate of the finFET;
c) covering the sides of the source and drain sections with sidewalls made of a dielectric material, wherein the sidewalls have tops;
d) replacing the top portions of the source and drain sections with a doped amorphous material comprising either doped amorphous silicon or doped amorphous silicon-germanium, the doped amorphous material having a second doping opposite to the first doping, wherein the doped amorphous material extends beyond the tops of the sidewalls;
e) performing sub-melt laser annealing of the doped amorphous material to form a doped crystalline material comprising either crystalline silicon or crystalline silicon-germanium, the doped crystalline material having the second doping to define the source and drain regions of the finFET, wherein the source and drain regions include respective expanded-area portions that extend beyond the tops of the sidewalls; and
f) removing any of the doped amorphous material that was not converted to the crystalline doped material in act e).

8. The finFET product according to claim 7, wherein the acts c) and d) comprise:
depositing a dielectric material over the tops and the sides of the source and drain sections to define tops of the dielectric material that reside directly above the source and drain sections;
selectively masking the dielectric material to leave the tops of the dielectric material exposed; and
etching through the tops of the dielectric material and into the source and drain sections to remove the top portions of the source and drain sections to define respective source and drain well structures having shortened source and drain top sections.

9. The finFET produce according to claim 8, wherein act d) comprises:
blanket depositing the doped amorphous material so that a portion of the doped amorphous material fills the source and drain well structures and resides upon the shortened source and drain top sections.

10. The finFET product according to claim 7, wherein act a) comprises defining multiple c-Si fins and further comprising simultaneously performing acts b) through f) on the multiple c-Si fins to form multiple source and drain regions for multiple finFETs.

11. The finFET product according to claim 7, wherein the act e) of sub-melt laser annealing includes scanning a laser beam over the doped a-Si to have a dwell time in the range from 10 ns to 500 ns.

12. The finFET product according to claim 11, wherein the scanning laser beam has a wavelength in the range from 200 nm to 11 microns.

13. A method of forming source and drain regions for finFETs, the method comprising:
a) defining multiple c-Si fins each having a first doping, opposite sides, a top section having a top portion with a top, and also having a source section;
b) covering the top and opposite sides of the central portion of each of the c-Si fins with a gate material to define the gates of the finFETs;
c) covering the sides of the source and drain sections of each c-Si fin with sidewalls made of a dielectric material;
d) replacing the top portions of the source and drain sections of each of the c-Si fins with a doped amorphous material comprising either doped amorphous silicon (a-Si) or doped amorphous silicon-germanium (a-SiGe) having a second doping opposite to the first doping, wherein the doped amorphous material extends beyond the tops of the sidewalls;
e) performing sub-melt laser annealing of the a-Si to form doped c-Si having the second doping to define the source and drain regions of the finFETs, wherein the source and drain regions include respective expanded-area portions that extend beyond the tops of the sidewalls; and
f) removing any of the doped amorphous material that was not converted to doped crystalline material in act e).

14. A method of forming a source region and a drain region for a finFET, comprising:
a) defining a c-Si fin having a first doping, opposite sides, a top section having a top portion with a top, and also having a source section and a drain section;
b) covering the top and opposite sides of the central portion of the c-Si fins with a gate material to define the gates of the finFETs;
c) covering the sides of the source and drain sections with sidewalls made of a dielectric material;
d) selectively removing the top portions of the source and drain sections;
e) replacing the top portions with a doped amorphous material that comprises either Si or SiGe, the doped amorphous material having a second doping opposite to the first doping using a blanket deposition of the doped amorphous material so that the doped amorphous material extends beyond the tops of the sidewalls;
f) performing sub-melt laser annealing to convert the doped amorphous material to a doped crystalline material comprising either Si or Ge and having the second doping to define the source and drain regions of the finFETs, wherein the doped crystalline material beyond the tops of the sidewalls;
g) removing any of the doped amorphous material that was not converted to the doped crystalline material during act f).
